(19) United States
(12) Patent Application Publication
(10) Pub. No.: US 2013/0248872 A1
(43) Pub. Date: Sep. 26, 2013

(54) SEMICONDUCTOR DEVICE, NITRIDE SEMICONDUCTOR CRYSTAL, METHOD FOR MANUFACTURING SEMICONDUCTOR DEVICE, AND METHOD FOR MANUFACTURING NITRIDE SEMICONDUCTOR CRYSTAL

(71) Applicant: FUJITSU LIMITED, Kawasaki-shi (JP)

(72) Inventors: Norikazu NAKAMURA, Sagamihara (JP); Atsushi YAMADA, Isehara (JP); Tetsuro ISHIGURO, Kawasaki (JP); Toyoo MIYAJIMA, Isehara (JP); Kenji IMANISHI, Atsugi (JP)

(73) Assignee: FUJITSU LIMITED, Kawasaki-shi (JP)

(21) Appl. No.: 13/762,847

(22) Filed: Feb. 8, 2013

(30) Foreign Application Priority Data
Mar. 26, 2012 (JP) 2012-070385

(51) Int. Cl. H01L 29/20; H01L 21/02

(52) U.S. Cl. CPC H01L 29/2003; H01L 21/0254
USPC 257/76; 438/478

(57) ABSTRACT

A semiconductor device includes: a nucleation layer formed over a substrate; a buffer layer formed over the nucleation layer; a first nitride semiconductor layer formed over the buffer layer; and a second nitride semiconductor layer formed over the first nitride semiconductor layer, wherein the ratio of yellow luminescence emission to band edge emission in photoluminescence is 400% or less and the twist value in an X-ray rocking curve is 1,000 arcsec or less.

### CROSS-REFERENCE TO RELATED APPLICATION

This application is based upon and claims the benefit of priority of the prior Japanese Patent Application No. 2012-070385, filed on Mar. 26, 2012, the entire contents of which are incorporated herein by reference.

### FIELD

The embodiments discussed herein are related to a semiconductor device, a nitride semiconductor crystal, a method for manufacturing a semiconductor device, and a method for manufacturing a nitride semiconductor crystal.

### BACKGROUND

Nitride semiconductors, for example, GaN, AlN, InN, and materials made from a mixed crystal thereof, have wide band gaps and have been used as high-output electronic devices, short-wavelength light-emitting devices, or the like. For example, GaN that is a nitride semiconductor has a band gap of 3.4 eV that is larger than the band gap of 1.1 eV of Si and the band gap of 1.4 eV of GaAs.

Examples of such high-output electronic devices include a field effect transistor (FET), in particular, a high electron mobility transistor (HEMT) (for example, Japanese Laid-open Patent Publication No. 2002-359256). Such a HEMT including a nitride semiconductor is used for high-output and high-efficiency amplifiers, high-power switching devices, or the like. Specifically, in a HEMT in which AlGaN is used for an electron supply layer and GaN is used for an electron transfer layer, piezoelectric polarization or the like occurs in AlGaN because of strain due to a lattice constant difference between AlGaN and GaN, and a high-concentration two-dimensional electron gas (2DEG) is generated. Consequently, such HEMT may operate at high voltages and be used for a high-voltage power device in a high-efficiency switching element, an electric car, or the like.

The HEMT including a nitride semiconductor is formed by epitaxial growth of a nitride semiconductor on a substrate. However, it is very difficult to produce a GaN substrate and the producing may result in high costs, so that the HEMT uses a single crystal substrate other than the GaN substrate. Examples of such substrates include a SiC substrate, a sapphire substrate, and a silicon (Si) substrate. Among those substrates, the Si substrate is produced easily having a relatively large diameter as compared with other substrates, is used in general, and is available inexpensively. Therefore, if the Si substrate is used for a HEMT including the nitride semiconductor, there is an advantage from the viewpoint of the cost.

The followings are reference documents.
[Document 1] Japanese Laid-open Patent Publication No. 2002-359256.

### SUMMARY

According to an aspect of the invention, a semiconductor device includes: a nucleation layer formed over a substrate; a buffer layer formed over the nucleation layer; a first nitride semiconductor layer formed over the buffer layer; and a second nitride semiconductor layer formed over the first nitride semiconductor layer, wherein the ratio of yellow luminescence emission to band edge emission in photoluminescence is 400% or less and the twist value in an X-ray rocking curve is 1,000 arcsec or less.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a characteristic diagram of capacitance after loading/capacitance before loading characteristics of samples;

FIGS. 2A and 2B are explanatory diagrams of samples in which a GaN layer is formed on a substrate;

FIG. 3 is a characteristic diagram of capacitance after loading/capacitance before loading characteristics of other samples;

FIG. 4 is an explanatory diagram of twist values of GaN and emission intensity ratios of YL/BE of other samples;

FIG. 5 is a structural diagram of a nitride semiconductor crystal in a first embodiment;

FIG. 6 is an image diagram of an amount of supply of a raw material gas in formation of a first nucleation layer and a second nucleation layer;

FIG. 7 is a structural diagram of a nitride semiconductor crystal in the first embodiment;

FIG. 8 is a structural diagram of a comparative nitride semiconductor crystal;

FIG. 9 is a characteristic diagram of capacitance after loading/capacitance before loading characteristics of nitride semiconductor crystals;

FIG. 10 is an explanatory diagram of twist values of GaN and emission intensity ratios of YL/BE of nitride semiconductor crystals;

FIGS. 11A and 11B are cross-sectional SEM images of a nucleation layer, a first nucleation layer, and a second nucleation layer;

FIG. 12 is a structural diagram of a semiconductor device in the first embodiment;

FIG. 13 is a structural diagram of other semiconductor device in the first embodiment;

FIG. 14 is a structural diagram of a semiconductor device in a second embodiment;

FIG. 15 is a circuit diagram of a PFC circuit in the second embodiment;

FIG. 16 is a circuit diagram of a power supply device in the second embodiment; and

FIG. 17 is a structural diagram of a high-output amplifier in the second embodiment.

### DESCRIPTION OF EMBODIMENTS

The embodiments will be described below. In this regard, the same members are indicated by the same reference numerals and further explanations thereof will not be provided.

While inventing the embodiments, observations were made regarding a related art. Such observations include the following, for example.

In a semiconductor device of the related art, for example, in the HEMT including a GaN layer crystal-grown on a Si substrate, such a phenomenon as current collapse may occur in which a drain current decreases to a large extent in an operation at a high voltage. It is believed that such current collapse occurs because of various factors, and the film quality of the GaN layer may be one of the factors. The quality of the GaN layer varies depending on a substrate, on which a crystal is grown, significantly.

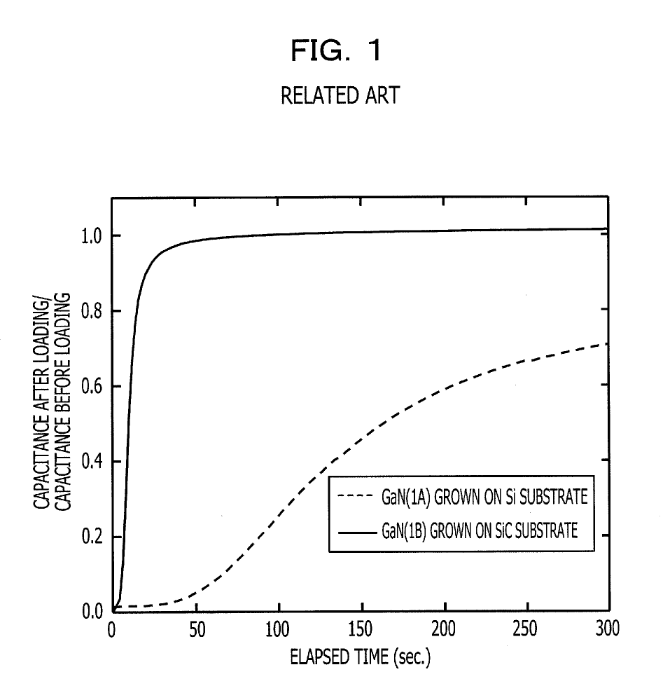

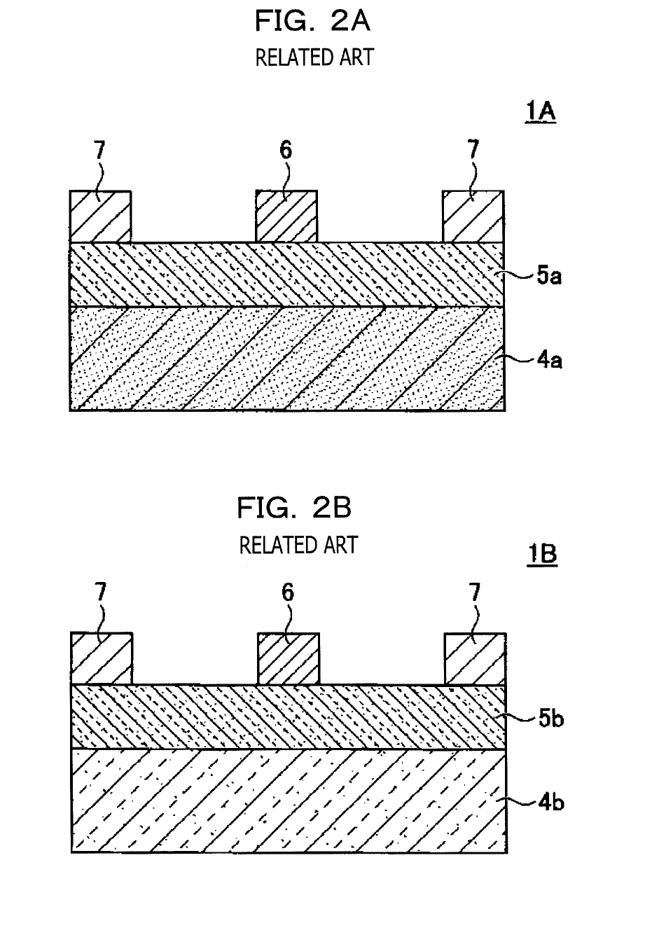

FIG. 1 depicts variations with time in capacitance of Samples 1A and 1B in which a GaN layer is crystal-grown on a substrate. As depicted in FIG. 2A, Sample 1A has a GaN layer 5a crystal-grown on a Si substrate 4a by metal organic vapor phase epitaxy (MOVPE) or the like, and a first electrode 6 and a second electrode 7 formed on the GaN layer 5a. As depicted in FIG. 2B, Sample 1B has a GaN layer 5b crystal-grown on a SiC substrate 4b by MOVPE or the like, and a first electrode 6 and a second electrode 7 formed on the GaN layer 5b. FIG. 1 depicts the elapsed time after a voltage of −30 V is applied and results of the measurement of a capacitance change after −30 V is applied relative to the capacitance before −30 V is applied.

In FIG. 1, the ratio of the capacitance after −30 V is applied relative to the capacitance before −30 V is applied is expressed as capacitance after loading/capacitance before loading. As depicted in FIG. 1, the capacitance of Sample 1B including the SiC substrate 4b depicted in FIG. 2B returns to the capacitance before the voltage is applied in several ten seconds from application of a voltage of −30 V. In comparison, the capacitance of Sample 1A including the Si substrate 4a depicted in FIG. 2A returns to only 70 percent of the capacitance before the voltage is applied even when 300 seconds have elapsed from application of a voltage of −30 V. If the recovery is delayed as described above, the on resistance increases, and characteristics of a semiconductor device, for example, a HEMT, are degraded. In the case where the SiC substrate is used, a semiconductor device which is advantageous from the viewpoint of characteristics as compared with a semiconductor device using the Si substrate may be produced. However, the SiC substrate is very expensive as compared with the Si substrate and it is difficult to produce the SiC substrate having a relatively large diameter. Therefore, a semiconductor device using the Si substrate as the substrate is preferable from the viewpoint of the cost.

### First Embodiment

In the case where a silicon (Si) substrate is used, in order to reduce the on resistance, a nitride semiconductor layer may be formed in such a way that the value of capacitance after loading/capacitance before loading becomes close to 1 in a short time in the same manner as GaN grown on a SiC substrate, as depicted in FIG. 1.

In the case where a nitride semiconductor layer is formed on the Si substrate, typically, a nucleation layer and a buffer layer are formed on the Si substrate, and an electron transfer layer and an electron supply layer are formed thereon. However, even when there are differences in electric characteristics of semiconductor devices, for example, HEMTs, differences in crystallinity and the like of electron transfer layers, electron supply layers, and the like are rarely observed, and it is difficult to find differences. That is, it has been difficult to find the conditions of the nitride semiconductor layers, for example, the electron transfer layer and the electron supply layer, under which the value of capacitance after loading/capacitance before loading comes close to 1, in other words, the on resistance is reduced, quickly.

The inventor has studied the physical state of the nitride semiconductor layer, based on the fact that there is an interrelation between the on resistance and the value of capacitance after loading/capacitance before loading of a produced semiconductor device, for example, a HEMT, as described above.

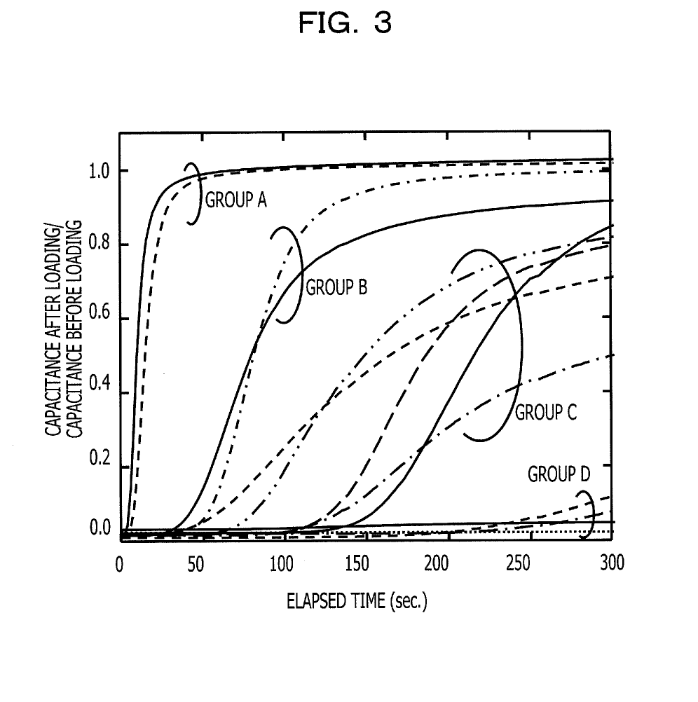

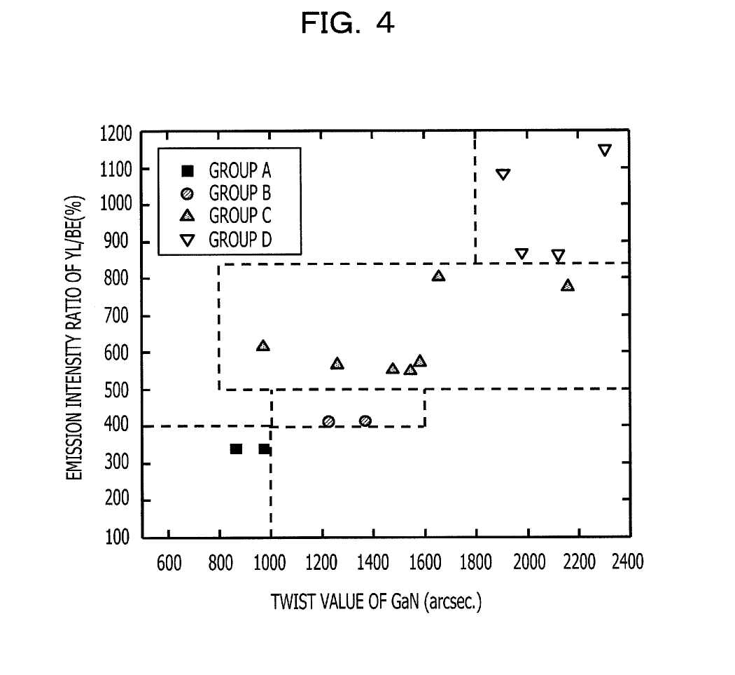

Specifically, samples having the same structure as the structure depicted in FIG. 2 were produced under various conditions, and interrelations between changes in the value of capacitance after loading/capacitance before loading and physical parameters were examined. As a result, as depicted in FIG. 3 and FIG. 4, it was found that there were interrelations among the emission intensity ratio of YL/BE, the twist value in the X-ray rocking curve, and the change in value of capacitance after loading/capacitance before loading. The emission intensity ratio of YL/BE refers to a ratio of the yellow luminescence emission intensity to the band edge emission intensity. As described above, the produced samples had the same structure as the structure depicted in FIG. 2, and the nucleation layer, the buffer layer, the GaN layer, and the like were formed under various forming conditions. The thus formed samples may be divided into Group A, Group B, Group C, and Group D, based on the degree of change in the value of capacitance after loading/capacitance before loading, as depicted in FIG. 3.

Group A is a group of samples, wherein values of capacitance after loading/capacitance before loading returned to about 1 within an elapsed time of 50 seconds. Group B is a group of samples, wherein elapsed times until values of capacitance after loading/capacitance before loading returned to 0.8 or more were 100 seconds or more and 150 seconds or less. Group C is a group of samples, wherein elapsed times until values of capacitance after loading/capacitance before loading returned to 0.6 or more were 150 seconds or more and 250 seconds or less. Group D is a group of samples, wherein values of capacitance after loading/capacitance before loading returned to 0.2 or less even when the elapsed time was 300 seconds or more.

FIG. 4 depicts the results of measurement of the emission intensity ratio of YL/BE and the twist value (twist value of GaN) in the X-ray rocking curve of these samples of Group A, Group B, Group C, and Group D. According to the results, the samples included in Group A exhibited emission intensity ratios of YL/BE within the range of 400% or less and twist values in the X-ray rocking curve within the range of 1,000 arcsec or less. The samples included in Group B exhibited emission intensity ratios of YL/BE within the range of more than 400% and 500% or less and twist values in the X-ray rocking curve within the range of more than 1,000 arcsec and 1,600 arcsec or less. The samples included in Group C exhibited emission intensity ratios of YL/BE within the range of more than 500% and about 830% or less and twist values in the X-ray rocking curve within the range of more than 800 arcsec and 2,400 arcsec or less. The samples included in Group D exhibited emission intensity ratios of YL/BE within the range of more than about 830% and 1,200% or less and twist values in the X-ray rocking curve within the range of more than 1,800 arcsec and 2,400 arcsec or less. Meanwhile, the film densities, composition ratios, and the like of the samples included in Group A, Group B, Group C, and Group D were measured, although differences were not observed clearly.

As described above, it was found that there was an interrelation between changes in the value of capacitance after loading/capacitance before loading, the emission intensity ratio of YL/BE, and the twist value in the X-ray rocking curve. Specifically, it was found that the value of capacitance after loading/capacitance before loading returned more quickly, that is, the on resistance was reduced, as the emission intensity ratio of YL/BE was reduced and as the twist value in the X-ray rocking curve was reduced.

As depicted in FIG. 3, among the samples included in Group A, Group B, Group C, and Group D, the samples included in Group A exhibited the values of capacitance after loading/capacitance before loading which came close to 1 in a shortest time. Therefore, even in the case where a Si substrate is used as the substrate, changes in the value of capacitance after loading/capacitance before loading may become close to that of the above-described sample using a SiC substrate insofar as the sample is included in Group A. Consequently, even in the case where a Si substrate is used as the substrate, the on resistance in a semiconductor device may be reduced by producing the semiconductor device while the same structure and condition as those of the sample included in Group A are employed. That is, it was found that the on resistance was reduced by producing the semiconductor device such that the emission intensity ratio of YL/BE of the GaN layer is within the range of 400% or less and the twist value in the X-ray rocking curve is within the range of 1,000 arcsec or less.

Nitride Semiconductor Crystal 101 in First Embodiment

Next, a nitride semiconductor crystal 101 to form a semiconductor device according to a first embodiment will be described.

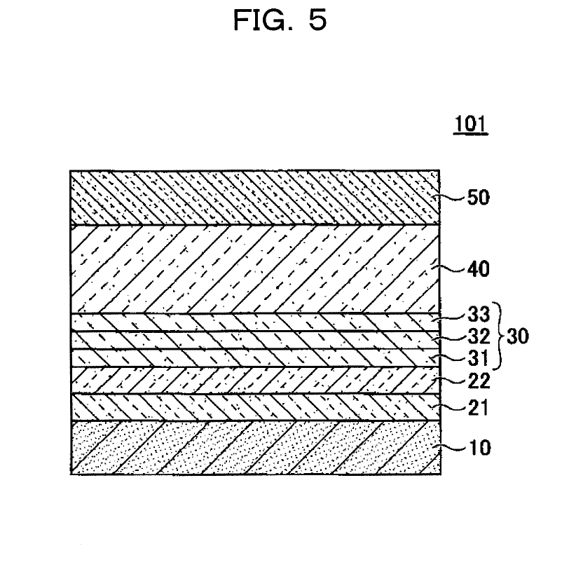

FIG. 5 depicts the structure of the nitride semiconductor crystal 101 according to the first embodiment. In the nitride semiconductor crystal 101 according to the first embodiment, a first nucleation layer 21, a second nucleation layer 22, a buffer layer 30, an electron transfer layer 40, and an electron supply layer 50 are epitaxially grown on a Si substrate 10 by MOVPE.

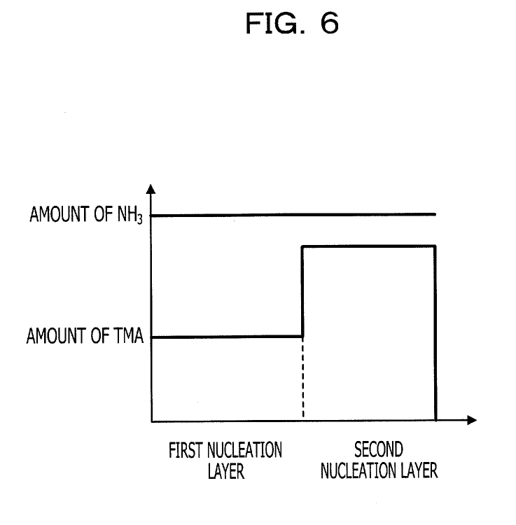

The first nucleation layer 21 and the second nucleation layer 22 are formed from AlN, trimethyl aluminum (TMA) is used as a raw material gas for Al, and ammonia (NH₃) is used as a raw material gas for N. The growth temperature in epitaxial growth of the first nucleation layer 21 and the second nucleation layer 22 is about 1,000° C., the growth pressure is about 20 kPa. As depicted in FIG. 6, first, the first nucleation layer 21 is formed in such a way that the molar supply ratio of TMA to NH₃, i.e. TMA:NH₃, is specified to be 100:1 and the film thickness is specified to be about 50 nm. Subsequently, the second nucleation layer 22 is formed in such a way that the molar supply ratio of TMA to NH₃, i.e. TMA:NH₃, is specified to be 10:1 and the film thickness is specified to be about 200 nm. FIG. 6 depicts an image of the relationship between the amount of TMA and the amount of NH₃ supplied when forming the first nucleation layer 21 and the second nucleation layer 22. It is preferable that the pressure in formation of the first nucleation layer 21 be nearly equal to the pressure in formation of the second nucleation layer 22. If these pressures are different from each other, a process of crystal growth changes. Therefore, it is preferable that the formation be performed at the same pressure as much as possible. In the first embodiment, a layer formed from the first nucleation layer 21 and the second nucleation layer 22 may be referred to as a nucleation layer.

The buffer layer 30 is formed from AlGaN, trimethyl gallium (TMG) is used as a raw material gas for Ga, TMA is used as a raw material gas for Al, and NH₃ is used as a raw material gas for N. In epitaxial growth of the buffer layer 30, the growth temperature is about 1,000° C., and the growth pressure is about 40 kPa. In the buffer layer 30, a first buffer layer 31, a second buffer layer 32, and a third buffer layer 33 are formed sequentially on the second nucleation layer 22. The first buffer layer 31 is formed from Al_{0.8}Ga_{0.2}N, the second buffer layer 32 is formed from Al_{0.5}Ga_{0.5}N, and the third buffer layer 33 is formed from Al_{0.2}Ga_{0.8}N.

The electron transfer layer 40 is formed from GaN, TMG is used as a raw material gas for Ga, and NH₃ is used as a raw material gas for N. In epitaxial growth of the electron transfer layer 40, the growth temperature is about 1,000° C., and the growth pressure is about 60 kPa.

The electron supply layer 50 is formed from AlGaN, TMG is used as a raw material gas for Ga, TMA is used as a raw material gas for Al, and NH₃ is used as a raw material gas for N. In epitaxial growth of the electron supply layer 50, the growth temperature is about 1,000° C., and the growth pressure is about 40 kPa.

The nitride semiconductor crystal 101 according to the first embodiment is produced by the above-described manufacturing method.

Nitride Semiconductor Crystal 102 in First Embodiment

Next, a nitride semiconductor crystal 102 to form a semiconductor device according to the first embodiment will be described. The structure of a buffer layer of the nitride semiconductor crystal 102 is different from that of the nitride semiconductor crystal 101.

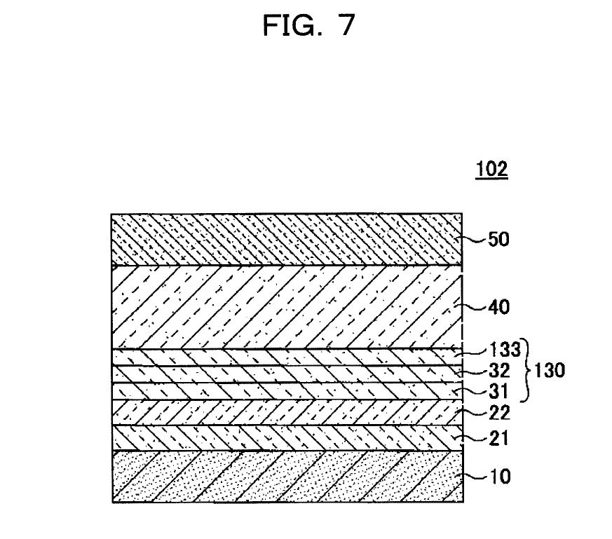

FIG. 7 depicts the structure of the nitride semiconductor crystal 102 according to the first embodiment. In the nitride semiconductor crystal 102 according to the first embodiment, a first nucleation layer 21, a second nucleation layer 22, a buffer layer 130, an electron transfer layer 40, and an electron supply layer 50 are epitaxially grown on a Si substrate 10 by MOVPE.

The first nucleation layer 21 and the second nucleation layer 22 are formed from AlN, TMA is used as a raw material gas for Al, and NH₃ is used as a raw material gas for N. The growth temperature in epitaxial growth of the first nucleation layer 21 and the second nucleation layer 22 is about 1,000° C., the growth pressure is about 20 kPa. As depicted in FIG. 6, first, the first nucleation layer 21 is formed in such a way that the molar supply ratio of TMA to NH₃, i.e. TMA:NH₃, is specified to be 100:1 and the film thickness is specified to be about 50 nm. Subsequently, the second nucleation layer 22 is formed in such a way that the molar supply ratio of TMA to NH₃, i.e. TMA:NH₃, is specified to be 10:1 and the film thickness is specified to be about 200 nm. FIG. 6 depicts the image of the relationship between the amount of TMA and the amount of NH₃ supplied when forming the first nucleation layer 21 and the second nucleation layer 22. It is preferable that the pressure in formation of the first nucleation layer 21 be nearly equal to the pressure in formation of the second nucleation layer 22. If these pressures are different from each other, a process of crystal growth changes. Therefore, it is preferable that the formation be performed at the same pressure as much as possible. In the first embodiment, a layer formed from the first nucleation layer 21 and the second nucleation layer 22 may be referred to as a nucleation layer.

The buffer layer 130 is formed from AlGaN, TMG is used as a raw material gas for Ga, TMA is used as a raw material gas for Al, and NH₃ is used as a raw material gas for N. In the buffer layer 130, a first buffer layer 31, a second buffer layer 32, and a third buffer layer 133 are formed sequentially on the second nucleation layer 22. The first buffer layer 31 is formed from Al_{0.8}Ga_{0.2}N, the second buffer layer 32 is formed from Al_{0.5}Ga_{0.5}N, and the third buffer layer 133 is formed from Al_{0.2}Ga_{0.8}N. In epitaxial growth of the buffer layer 130, the growth temperature is about 1,000° C., the growth pressures of the first buffer layer 31 and the second buffer layer 32 are about 40 kPa, and the growth pressure of the third buffer layer 133 is about 20 kPa. In this manner, the growth rate may be increased and the content of carbon may be increased, as described later, by reducing the growth pressure of the third buffer layer 133.

The electron transfer layer 40 is formed from GaN, TMG is used as a raw material gas for Ga, and NH₃ is used as a raw material gas for N. In epitaxial growth of the electron transfer layer 40, the growth temperature is about 1,000° C., and the growth pressure is about 60 kPa.

The electron supply layer 50 is formed from AlGaN, TMG is used as a raw material gas for Ga, TMA is used as a raw material gas for Al, and NH₃ is used as a raw material gas for N. In epitaxial growth of the electron supply layer 50, the growth temperature is about 1,000° C., and the growth pressure is about 40 kPa.

The nitride semiconductor crystal 102 according to the first embodiment is produced by the above-described manufacturing method.

Comparative Nitride Semiconductor Crystal 901

Next, a comparative nitride semiconductor crystal 901 produced in order to explain the first embodiment will be described.

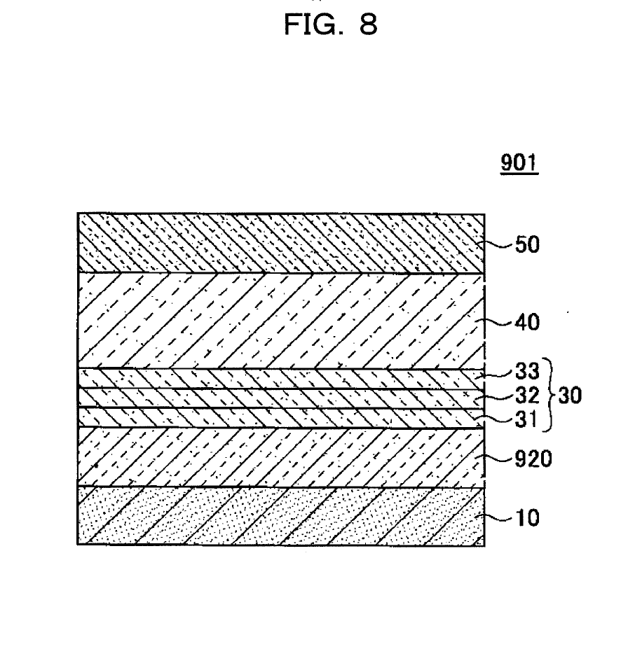

FIG. 8 depicts the structure of the comparative nitride semiconductor crystal 901. In the comparative nitride semiconductor crystal 901, a nucleation layer 920, a buffer layer 30, an electron transfer layer 40, and an electron supply layer 50 are epitaxially grown on a Si substrate 10 by MOVPE. Therefore, the nucleation layer 920 of the comparative nitride semiconductor crystal 901 is different from that of the nitride semiconductor crystal 101 according to the first embodiment and the nucleation layer 920 and the buffer layer 30 of the comparative nitride semiconductor crystal 901 are different from those of the nitride semiconductor crystal 102 according to the first embodiment.

The nucleation layer 920 is formed from AlN, TMA is used as a raw material gas for Al, and NH₃ is used as a raw material gas for N. The growth temperature in epitaxial growth of the nucleation layer 920 is about 1,000° C., the growth pressure is about 20 kPa. The nucleation layer 920 is formed in such a way that the molar supply ratio of TMA to NH₃, i.e. TMA:NH₃, is specified to be 100:1 and the film thickness is specified to be about 250 nm.

The buffer layer 30 is formed from AlGaN, trimethyl gallium (TMG) is used as a raw material gas for Ga, TMA is used as a raw material gas for Al, and NH₃ is used as a raw material gas for N. In epitaxial growth of the buffer layer 30, the growth temperature is about 1,000° C., and the growth pressure is about 40 kPa. In the buffer layer 30, a first buffer layer 31, a second buffer layer 32, and a third buffer layer 33 are formed sequentially on the nucleation layer 920. The first buffer layer 31 is formed from Al_{0.8}Ga_{0.2}N, the second buffer layer 32 is formed from Al_{0.5}Ga_{0.5}N, and the third buffer layer 33 is formed from Al_{0.2}Ga_{0.8}N.

The electron transfer layer 40 is formed from GaN, TMG is used as a raw material gas for Ga, and NH₃ is used as a raw material gas for N. In epitaxial growth of the electron transfer layer 40, the growth temperature is about 1,000° C., and the growth pressure is about 60 kPa.

The electron supply layer 50 is formed from AlGaN, TMG is used as a raw material gas for Ga, TMA is used as a raw material gas for Al, and NH₃ is used as a raw material gas for N. In epitaxial growth of the electron supply layer 50, the growth temperature is about 1,000° C., and the growth pressure is about 40 kPa.

The comparative nitride semiconductor crystal 901 is produced by the above-described manufacturing method.

Evaluation of Nitride Semiconductor Layer

Next, the nitride semiconductor crystals 101 and 102 according to the first embodiment and the comparative nitride semiconductor crystal 901 were evaluated and measured. The results will be described.

The nitride semiconductor crystals 101 and 102 according to the first embodiment and the comparative nitride semiconductor crystal 901 were subjected to a film thickness measurement by cross-sectional transmission electron microscope (TEM) observation and element analysis by energy dispersive X-ray spectroscopy (EDX). EDX refers to an instrument using energy dispersive X-ray analysis. As a result, the film thicknesses, composition ratios of the constituent elements, and the like of all of the nitride semiconductor crystals 101 and 102 according to the first embodiment and the comparative nitride semiconductor crystal 901 were nearly equal.

Atomic force microscope (AFM) images were observed on the surfaces of the first nucleation layer 21 and the second nucleation layer 22 of the nitride semiconductor crystal 101 according to the first embodiment. As a result, the surface roughness of the second nucleation layer 22 was small as compared with the surface roughness of the first nucleation layer 21.

The buffer layer 130 of the nitride semiconductor crystal 102 according to the first embodiment and the buffer layer 30 of the comparative nitride semiconductor crystal 901 were analyzed by a secondary ion-microprobe mass spectrometer (SIMS). As a result, in the buffer layer 30, the amount of admixture of carbon decreased as the Al composition decreased, whereas in the buffer layer 130, the amount of admixture of carbon into the third buffer layer 133 was the largest. That is, in the buffer layer 130, the amount of admixture of carbon into the third buffer layer 133 was larger than the amounts of admixture of carbon into the first buffer layer 31 and the second buffer layer 32. The reason for this is estimated that the growth pressure in formation of the third buffer layer 133 was lower than the growth pressures in formation of the first buffer layer 31 and the second buffer layer 32, and the growth rate of the third buffer layer 133 was high.

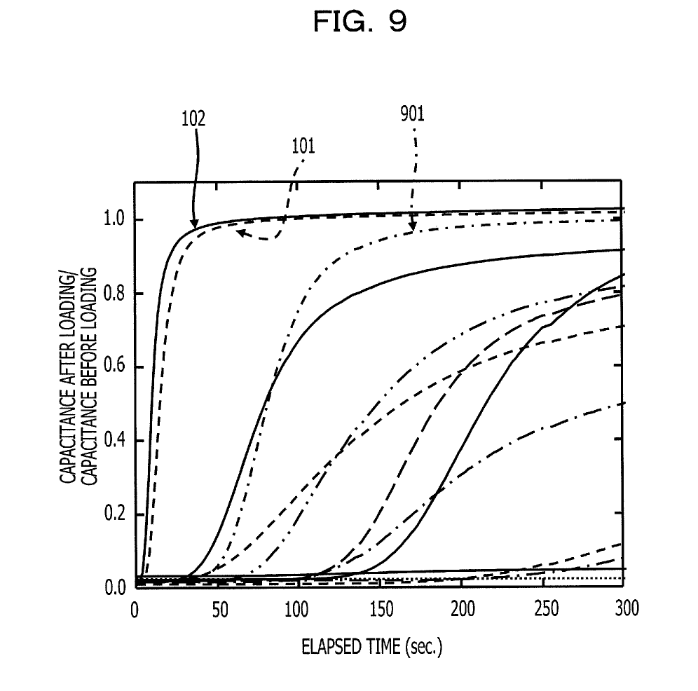

As depicted in FIG. 9, the nitride semiconductor crystals 101 and 102 according to the first embodiment and the comparative nitride semiconductor crystal 901 were subjected to evaluation of current collapse, as with the case depicted in FIG. 3. Specifically, as with the case depicted in FIG. 1, a voltage of −30 V was applied once between the electrodes (not illustrated) and the relationship between the elapsed time and the value of capacitance after loading/capacitance before loading was examined. As a result, the values of capacitance after loading/capacitance before loading of the nitride semiconductor crystals 101 and 102 according to the first embodiment returned to about 1 about 30 seconds later. The nitride semiconductor crystal 102 according to the first embodiment returned earlier than the nitride semiconductor crystal 101 according to the first embodiment. In comparison, the elapsed time until the value of capacitance after loading/capacitance before loading of the comparative nitride semiconductor crystal 901 returned to about 1 was about 200 seconds. Therefore, it is estimated that the on resistances of the semiconductor devices produced based on the nitride semiconductor crystals 101 and 102 according to the first embodiment are lower than the on resistance of the semiconductor device produced based on the comparative nitride semiconductor crystal 901. It is estimated from FIG. 9 that among these three types, the semiconductor device produced based on the nitride semiconductor crystal 102 has the lowest on resistance.

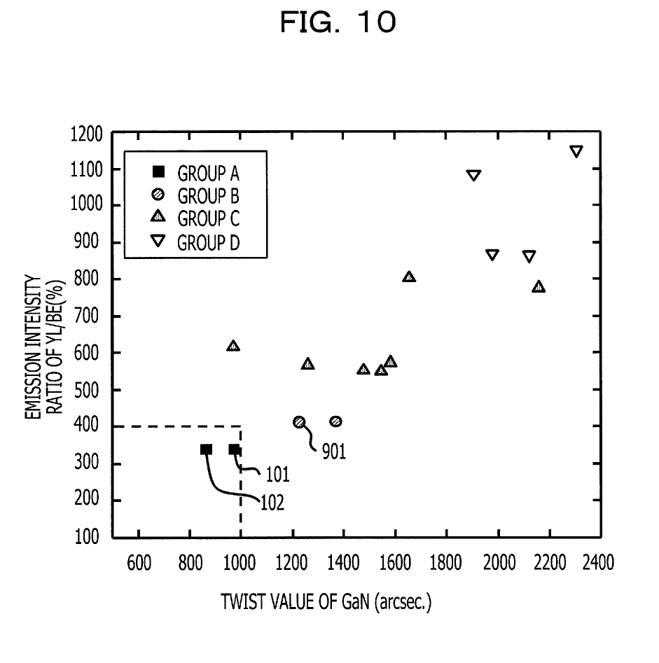

As depicted in FIG. 10, the nitride semiconductor crystals 101 and 102 according to the first embodiment and the comparative nitride semiconductor crystal 901 were subjected to measurements of the emission intensity ratio of YL/BE and the twist value in the X-ray rocking curve, as with the case depicted in FIG. 4. As a result, as for the nitride semiconductor crystals 101 and 102 according to the first embodiment, the emission intensity ratios of YL/BE were within the range of 400% or less, and the twist values in the X-ray rocking curve were within the range of 1,000 arcsec or less. In comparison, as for the comparative nitride semiconductor crystal 901, the emission intensity ratio of YL/BE was out of the range of 400% or less, and the twist value in the X-ray rocking curve was out of the range of 1,000 arcsec or less.

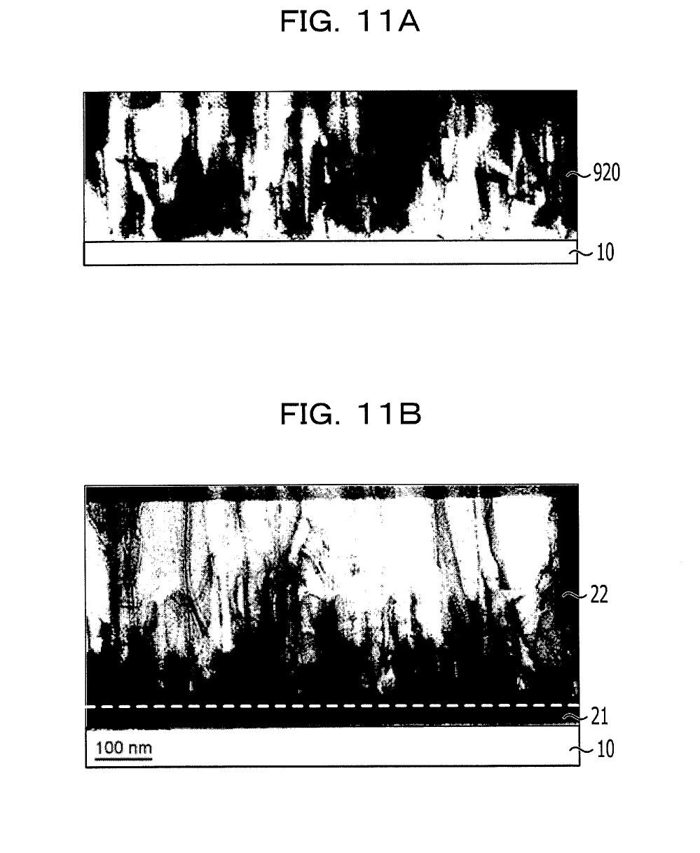

FIGS. 11A and 11B depict cross-sectional scanning electron microscope (SEM) images of the first nucleation layer 21 and the second nucleation layer 22 of the nitride semiconductor crystal 101 according to the first embodiment and the nucleation layer 920 of the comparative nitride semiconductor crystal 901. FIG. 11A depicts the SEM image of the nucleation layer 920 of the comparative nitride semiconductor crystal 901. FIG. 11B depicts the SEM image of the first nucleation layer 21 and the second nucleation layer 22 of the nitride semiconductor crystal 101 according to the first embodiment.

Semiconductor Device

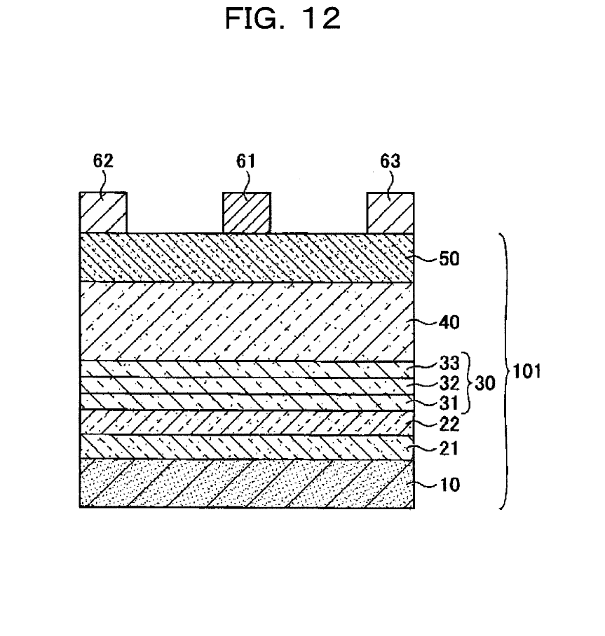

Next, a semiconductor device according to the first embodiment will be described. The semiconductor device according to the first embodiment is a semiconductor device including the nitride semiconductor crystal 101 according to the first embodiment. In the semiconductor device according to the first embodiment, as depicted in FIG. 12, a gate electrode 61, a source electrode 62, and a drain electrode 63 are formed on the electron supply layer 50 of the nitride semiconductor crystal 101 according to the first embodiment. That is, the gate electrode 61, the source electrode 62, and the drain electrode 63 are formed on a structure in which the first nucleation layer 21, the second nucleation layer 22, the buffer layer 30, the electron transfer layer 40, and the electron supply layer 50 are formed on the Si substrate 10. The first nucleation layer 21, the second nucleation layer 22, the buffer layer 30, the electron transfer layer 40, and the electron supply layer 50 are formed through epitaxial growth by MOVPE.

As described above, since the value of capacitance after loading/capacitance before loading of the nitride semiconductor crystal 101 according to the first embodiment returns to 1 in a relatively short time, the on resistance of the semiconductor device according to the first embodiment is low.

Other Semiconductor Device

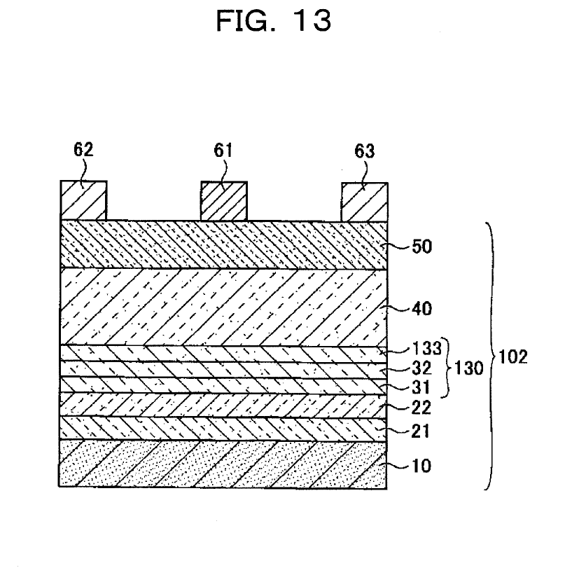

Next, another semiconductor device according to the first embodiment will be described. The other semiconductor device according to the first embodiment is a semiconductor device including the nitride semiconductor crystal 102 according to the first embodiment. In the other semiconductor device according to the first embodiment, as depicted in FIG. 13, a gate electrode 61, a source electrode 62, and a drain electrode 63 are formed on the electron supply layer 50 of the nitride semiconductor crystal 102 according to the first embodiment. That is, the gate electrode 61, the source electrode 62, and the drain electrode 63 are formed on a structure in which the first nucleation layer 21, the second nucleation layer 22, the buffer layer 130, the electron transfer layer 40, and the electron supply layer 50 are formed on the Si substrate 10. The first nucleation layer 21, the second nucleation layer 22, the buffer layer 130, the electron transfer layer 40, and the electron supply layer 50 are formed through epitaxial growth by MOVPE.

As described above, the on resistance of the other semiconductor device according to the first embodiment is low because the value of capacitance after loading/capacitance before loading of the nitride semiconductor crystal 102 according to the first embodiment returns to 1 in a relatively short time.

### Second Embodiment

Next, a second embodiment will be described. The second embodiment is a semiconductor device, a power supply apparatus, and a high-frequency amplifier.

Semiconductor Device

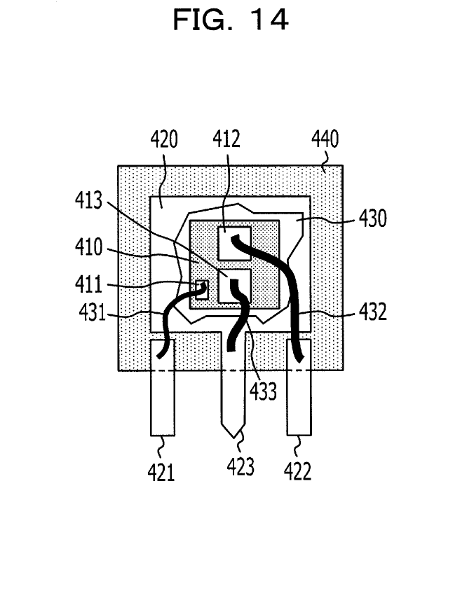

The semiconductor device according to the second embodiment is produced by subjecting the semiconductor device according to the first embodiment to discrete-packaging. The thus discretely packaged semiconductor device will be described with reference to FIG. 14. In this regard, FIG. 14 schematically depicts the inside of the discretely packaged semiconductor device, and the arrangement of electrodes and the like are different from those described in the first embodiment.

The semiconductor device produced in the first embodiment is cut by dicing or the like so as to produce a semiconductor chip 410 of a HEMT of a GaN base semiconductor material. The semiconductor chip 410 is fixed to a lead frame 420 with a die-attach agent 430, for example, solder. The semiconductor chip 410 corresponds to the semiconductor device according to the first embodiment.

A gate electrode 411 is connected to a gate lead 421 with a bonding wire 431, a source electrode 412 is connected to a source lead 422 with a bonding wire 432, and a drain electrode 413 is connected to a drain lead 423 with a bonding wire 433. The bonding wires 431, 432, and 433 are formed from a metal material, for example, Al. In the second embodiment, the gate electrode 411 is one type of a gate electrode pad and is connected to the gate electrode 61 of the semiconductor device according to the first embodiment. The source electrode 412 is one type of a source electrode pad and is connected to the source electrode 62 of the semiconductor device according to the first embodiment. The drain electrode 413 is one type of a drain electrode pad and is connected to the drain electrode 63 of the semiconductor device according to the first embodiment.

Resin sealing with a mold resin 440 is performed by a transfer mold method. In this manner, a discretely packaged semiconductor device of a HEMT using a GaN base semiconductor material may be produced.

Power Factor Correction Circuit, Power Supply Apparatus, and High-Frequency Amplifier

Next, a power factor correction (PFC) circuit, a power supply apparatus, and a high-frequency amplifier according to the second embodiment will be described. The PFC circuit, the power supply apparatus, and the high-frequency amplifier according to the second embodiment are the PFC circuit, the power supply apparatus, and the high-frequency amplifier including any one of semiconductor devices according to the first embodiment.

PFC Circuit

The PFC circuit according to the second embodiment will be described. The PFC circuit according to the second embodiment includes the semiconductor device according to the first embodiment.

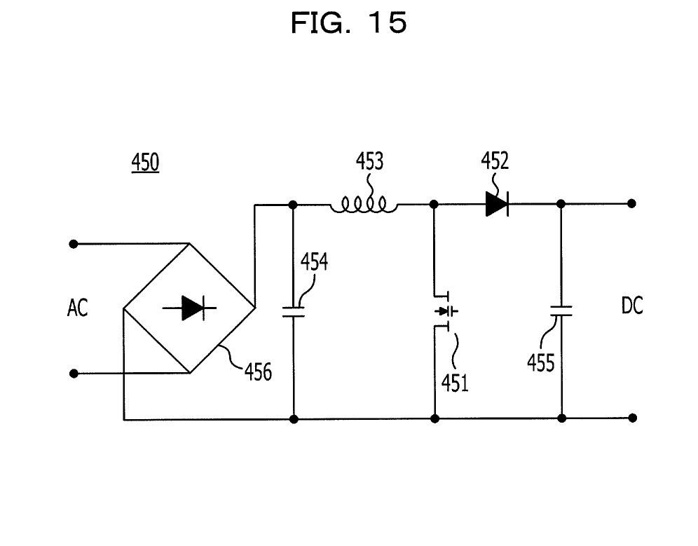

The PFC circuit according to the second embodiment will be described with reference to FIG. 15. The PFC circuit 450 according to the second embodiment includes a switch element (transistor) 451, a diode 452, a choke coil 453, capacitors 454 and 455, a diode bridge 456, and an alternating current power supply (not illustrated). A HEMT, which is the semiconductor device according to the first embodiment, is used for the switch element 451.

In the PFC circuit 450, the drain electrode of the switch element 451, the anode terminal of the diode 452, and one terminal of the choke coil 453 are connected. In addition, the source electrode of the switch element 451, one terminal of the capacitor 454, and one terminal of the capacitor 455 are connected, and the other terminal of the capacitor 454 and the other terminal of the choke coil 453 are connected. The other terminal of the capacitor 455 and the cathode terminal of the diode 452 are connected, and the alternating current power supply, although not illustrated in the drawing, is connected between the two terminals of the capacitor 454 through the diode bridge 456. In the above-described PFC circuit 450, a direct current (DC) is output from between the two terminals of the capacitor 455.

Power Supply Apparatus

The power supply apparatus according to the second embodiment will be described. The power supply apparatus according to the second embodiment is a power supply apparatus including the HEMT, which is the semiconductor device according to the first embodiment.

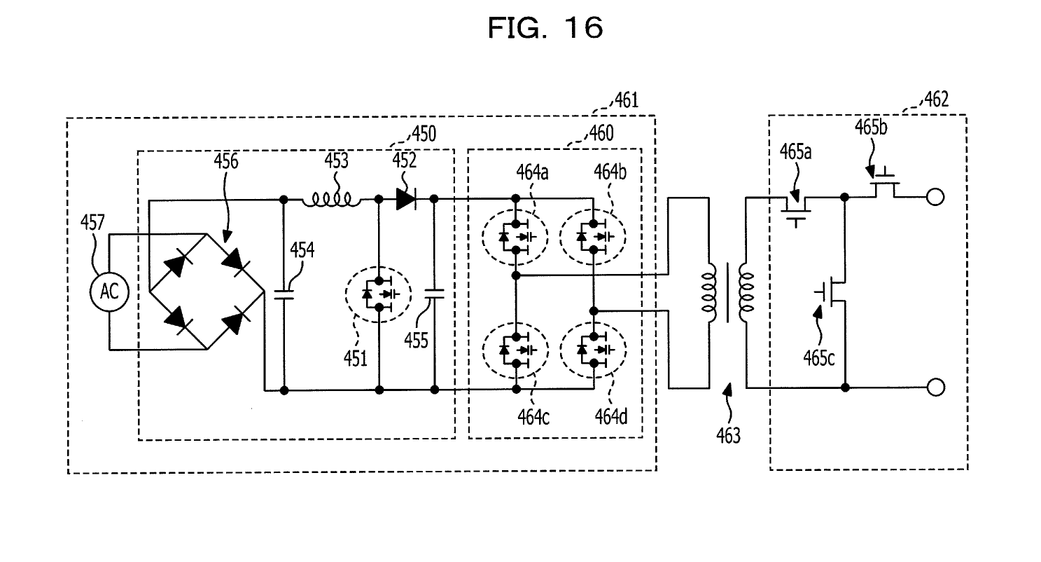

The power supply apparatus according to the second embodiment will be described with reference to FIG. 16. The power supply apparatus according to the second embodiment has a structure including the above-described PFC circuit 450 according to the second embodiment.

The power supply apparatus according to the second embodiment includes a high-voltage primary circuit 461, a low-voltage secondary circuit 462, and a transformer 463 disposed between the primary circuit 461 and the secondary circuit 462.

The primary circuit 461 includes the above-described PFC circuit 450 according to the second embodiment and an inverter circuit, for example, a full bridge inverter circuit 460, connected between the two terminals of the capacitor 455 of the PFC circuit 450. The full bridge inverter circuit 460 includes a plurality of, in this case, four switch elements 464a, 464b, 464c, and 464d. The secondary circuit 462 includes a plurality of, in this case, three switch elements 465a, 465b, and 465c. An alternating current power supply 457 is connected to the diode bridge 456.

In the second embodiment, the HEMT, which is the semiconductor device according to the first or second embodiment is used in the switch element 451 of the PFC circuit 450 in the primary circuit 461. In addition, the HEMT, which is the semiconductor device according to the first or second embodiment is used in the switch elements 464a, 464b, 464c, and 464d in the full bridge inverter circuit 460. Meanwhile, a FET having a common MIS structure using silicon is used for the switch elements 465a, 465b, and 465c in the secondary circuit 462.

High-Frequency Amplifier

The high-frequency amplifier according to the second embodiment will be described. The high-frequency amplifier according to the second embodiment has a structure including the HEMT, which is the semiconductor device according to the first embodiment.

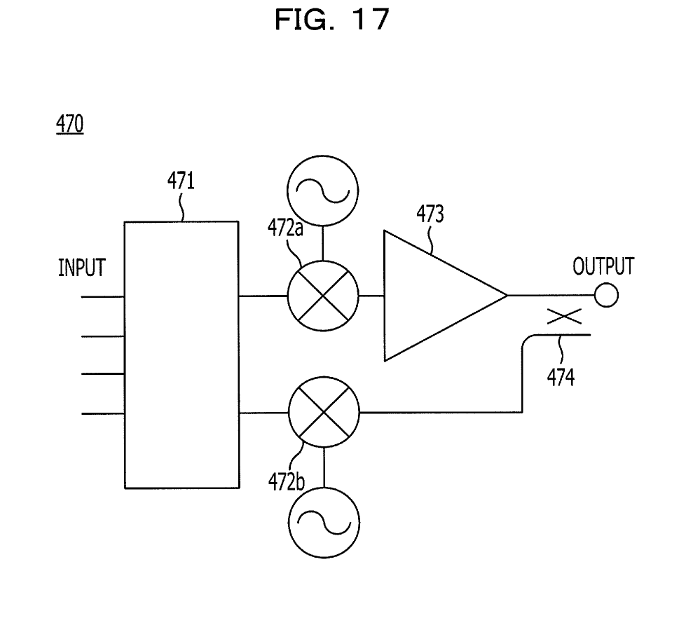

The high-frequency amplifier 470 according to the second embodiment will be described with reference to FIG. 17. The high-frequency amplifier 470 according to the second embodiment includes a digital predistortion circuit 471, mixers 472a and 472b, a power amplifier 473, and a directional coupler 474.

The digital predistortion circuit 471 compensates for nonlinear distortion of an input signal. The mixer 472a mixes the input signal, in which nonlinear distortion has been compensated for, and an alternating current signal. The power amplifier 473 amplifies the input signal mixed with the alternating current signal and includes the HEMT, which is the semiconductor device according to the first embodiment. The directional coupler 474 performs, for example, monitoring of the input signal and the output signal. In FIG. 17, the signal on the output side may be mixed with an alternating current signal by the mixer 472b and is sent to the digital predistortion circuit 471 by, for example, switching.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A semiconductor device comprising:
a nucleation layer formed over a substrate;
a buffer layer formed over the nucleation layer;
a first nitride semiconductor layer formed over the buffer layer; and
a second nitride semiconductor layer formed over the first nitride semiconductor layer, wherein
the ratio of yellow luminescence emission to band edge emission in photoluminescence is 400% or less and the twist value in an X-ray rocking curve is 1,000 arcsec or less.

2. The semiconductor device according to claim 1, wherein
the substrate is a silicon substrate.

3. The semiconductor device according to claim 1, wherein
the nucleation layer is formed from a material containing AlN.

4. The semiconductor device according to claim 1, wherein
the buffer layer includes a plurality of layers in which composition ratios of AlGaN are different from each other, and
among the plurality of layers, the amount of carbon contained in a layer near the first nitride semiconductor layer is larger than the amount of carbon contained in a layer near the nucleation layer.

5. The semiconductor device according to claim 1, wherein
the first nitride semiconductor layer is formed from a material containing GaN.

6. The semiconductor device according to claim 1, wherein
the second nitride semiconductor layer is formed from a material containing AlGaN.

7. The semiconductor device according to claim 1, further comprising
a gate electrode, a source electrode, and a drain electrode are formed over the second nitride semiconductor layer.

8. The semiconductor device according to claim 1, wherein
the semiconductor device is a HEMT.

9. A nitride semiconductor crystal comprising:
a nucleation layer formed over a substrate;
a buffer layer formed over the nucleation layer;
a first nitride semiconductor layer formed over the buffer layer; and
a second nitride semiconductor layer formed over the first nitride semiconductor layer, wherein
the ratio of yellow luminescence emission to band edge emission in photoluminescence is 400% or less and the twist value in an X-ray rocking curve is 1,000 arcsec or less.

10. The nitride semiconductor crystal according to claim 9, wherein
the substrate is a silicon substrate.

11. The nitride semiconductor crystal according to claim 9, wherein
the nucleation layer is formed from a material containing AlN.

12. The nitride semiconductor crystal according to claim 9, wherein
the buffer layer includes a plurality of layers in which composition ratios of AlGaN are different from each other, and
among the plurality of layers, the amount of carbon contained in a layer near the first nitride semiconductor layer is larger than the amount of carbon contained in a layer near the nucleation layer.

13. The nitride semiconductor crystal according to claim 9, wherein
the first nitride semiconductor layer is formed from a material containing GaN.

14. The nitride semiconductor crystal according to claim 9, wherein
the second nitride semiconductor layer is formed from a material containing AlGaN.

15. A method for manufacturing a semiconductor device, the method comprising:
forming a first nucleation layer from AlN over a silicon substrate;
forming a second nucleation layer from AlN over the first nucleation layer;
forming a buffer layer over the second nucleation layer;
forming a first nitride semiconductor layer over the buffer layer; and
forming a second nitride semiconductor layer over the first nitride semiconductor layer, wherein
the first nucleation layer and the second nucleation layer are formed by MOVPE in which TMA and ammonia serve as raw material gases,
the amount of supply of TMA relative to ammonia when forming the second nucleation layer is larger than the amount of supply of TMA relative to ammonia when forming the first nucleation layer, and
the pressure when forming the first nucleation layer is substantially equal to the pressure when forming the second nucleation layer.

16. The method for manufacturing a semiconductor device, according to claim 15, wherein
the buffer layer includes a plurality of layers which are formed by MOVPE and in which composition ratios of AlGaN are different from each other, and
among the plurality of layers, the pressure when forming a layer near the first nitride semiconductor layer is lower than the pressure when forming a layer near the second nucleation layer.

17. A method for manufacturing a nitride semiconductor crystal, the method comprising:
forming a first nucleation layer from AlN over a silicon substrate;
forming a second nucleation layer from AlN over the first nucleation layer;
forming a buffer layer over the second nucleation layer;
forming a first nitride semiconductor layer over the buffer layer; and
forming a second nitride semiconductor layer over the first nitride semiconductor layer, wherein
the first nucleation layer and the second nucleation layer are formed by MOVPE in which TMA and ammonia serve as raw material gases,
the amount of supply of TMA relative to ammonia when forming the second nucleation layer is larger than the amount of supply of TMA relative to ammonia when forming the first nucleation layer, and
the pressure when forming the first nucleation layer is substantially equal to the pressure when forming the second nucleation layer.

18. The method for manufacturing a nitride semiconductor crystal, according to claim 17, wherein
the buffer layer includes a plurality of layers which are formed by MOVPE and in which composition ratios of AlGaN are different from each other, and
among the plurality of layers, the pressure when forming a layer near the first nitride semiconductor layer is lower than the pressure when forming a layer near the second nucleation layer.
